(19) United States
(12) Patent Application Publication
(10) Pub. No.: US 2026/0052913 A1
(43) Pub. Date: Feb. 19, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Hui-Lin Wang, Taipei City (TW); Chen-Yi Weng, New Taipei City (TW); Po-Kai Hsu, Tainan City (TW); Hung-Yueh Chen, Hsinchu City (TW)

(73) Assignee: UNITED MICROELECTRONICS CORP., Hsin-Chu City (TW)

(21) Appl. No.: 18/902,954

(22) Filed: Oct. 1, 2024

(30) Foreign Application Priority Data
Aug. 16, 2024 (TW) 113130833

(51) Int. Cl. H10N 70/00; H10B 63/00

(52) U.S. Cl. CPC H10N 70/8833; H10B 63/30; H10N 70/063; H10N 70/066; H10N 70/068; H10N 70/841

(57) ABSTRACT

A method for fabricating a resistive random access memory (RRAM) includes the steps of first forming an interlayer dielectric (ILD) layer on a substrate, forming a first stop layer on the ILD layer, forming a recess in the first stop layer, forming a bottom electrode in the recess, forming a metal oxide layer on the bottom electrode, forming a top electrode on the metal oxide layer, patterning the top electrode and the metal oxide layer, and then forming a spacer adjacent to the top electrode and the metal oxide layer.

### BACKGROUND OF THE INVENTION

### 1. Field of the Invention

The invention relates to a semiconductor device, and more particularly to a resistive random access memory (RRAM) device.

### 2. Description of the Prior Art

Non-volatile memory devices have the advantages of retaining data even if the electrical power is being cut off, hence non-volatile memory devices have been widely used in most appliances today for maintaining proper operation of the electronic products. Currently, a popular non-volatile memory device being developed today is referred to as resistive random access memory (RRAM), which has the advantages of low voltage and short erase time under write operation, long memory duration, no damage under read operation, multiphase memory, simple structure, and small size. With all these benefits, RRAM devices are likely to be used in various personal computers and electronic equipment in the coming future.

In integrated circuits, RRAM is a merging technology applied for the next generation non-volatile memory devices. Specifically, RRAM is a memory structure having a resistive random access memory array, in which each of the resistive random access memory units uses resistance values to store one bit of data instead of electrical potentials. In particular, each of the resistive random access memory units include a resistance material layer that could be used to adjust resistance value for demonstrating “0” or “1”.

One approach to optimize RRAM array is to minimize its size as much as possible. Nevertheless, as size of the device decrease, fabrication cost and complexity also increase accordingly. Hence, how to lower the overall cost while maintaining yield of the product has become a major challenge in this field.

### SUMMARY OF THE INVENTION

According to an embodiment of the present invention, a method for fabricating a resistive random access memory (RRAM) includes the steps of first forming an interlayer dielectric (ILD) layer on a substrate, forming a first stop layer on the ILD layer, forming a recess in the first stop layer, forming a bottom electrode in the recess, forming a metal oxide layer on the bottom electrode, forming a top electrode on the metal oxide layer, patterning the top electrode and the metal oxide layer, and then forming a spacer adjacent to the top electrode and the metal oxide layer.

According to another aspect of the present invention, a resistive random access memory (RRAM) includes an interlayer dielectric (ILD) layer on a substrate, a contact plug in the ILD layer, a bottom electrode on the contact plug, and a first stop layer around the bottom electrode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-11 illustrate a method for fabricating a semiconductor device according to an embodiment of the present invention.

### DETAILED DESCRIPTION

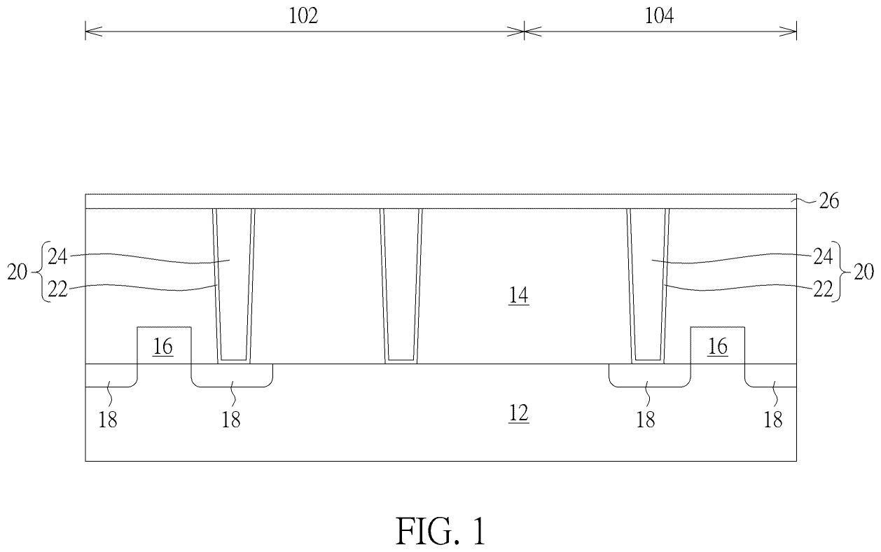

Referring to FIGS. 1-11, FIGS. 1-11 illustrate a method for fabricating a semiconductor device, or more specifically a RRAM device according to an embodiment of the present invention. As shown in FIG. 1, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a memory region 102 and a logic region 104 are defined on the substrate 12.

Active devices such as metal-oxide semiconductor (MOS) transistors, passive devices, conductive layers, and interlayer dielectric (ILD) layer 14 could also be formed on top of the substrate 12 on both memory region 102 and logic region 104. More specifically, planar MOS transistors or non-planar (such as FinFETs) MOS transistors could be formed on the substrate 12, in which the MOS transistors could include transistor elements such as gate structures 16 (for example metal gates) and source/drain regions 18, spacer, epitaxial layer, and contact etch stop layer (CESL). The ILD layer 14 could be formed on the substrate 12 to cover the MOS transistors, and a plurality of contact plugs 20 could be formed in the ILD layer 14 to electrically connect to the gate structures 16 and/or source/drain regions 18 of MOS transistors. Since the fabrication of planar or non-planar transistors and ILD layer is well known to those skilled in the art, the details of which are not explained herein for the sake of brevity.

In this embodiment, the formation of the contact plugs 20 could be accomplished by first conducting a pattern transfer process by using a patterned mask (not shown) as mask to remove part of the ILD layer 14 on the memory region 102 and logic region 104 for forming contact holes (not shown) exposing the source/drain regions 18 underneath. Next, metal or conductive materials including a barrier layer 22 selected from the group consisting of titanium (Ti), titanium nitride (TiN), tantalum (Ta), and tantalum nitride (TaN) and a metal layer 24 selected from the group consisting of tungsten (W), copper (Cu), aluminum (Al), titanium aluminide (TiAl), and cobalt tungsten phosphide (CoWP) are deposited into the contact holes, and then a planarizing process such as chemical mechanical polishing (CMP) process is conducted to remove part of the metal for forming contact plugs 20 or metal interconnections in the contact holes electrically connecting the source/drain regions 18.

Next, a stop layer 26 is formed on the surface of the ILD layer 14 and the contact plugs 20. In this embodiment, the ILD layer 14 is preferably made of silicon oxide such as tetraethyl orthosilicate (TEOS) and the stop layer 26 is made of nitrogen doped carbide (NDC), silicon nitride, silicon carbon nitride (SiCN), silicon oxynitride (SiON), or combination thereof.

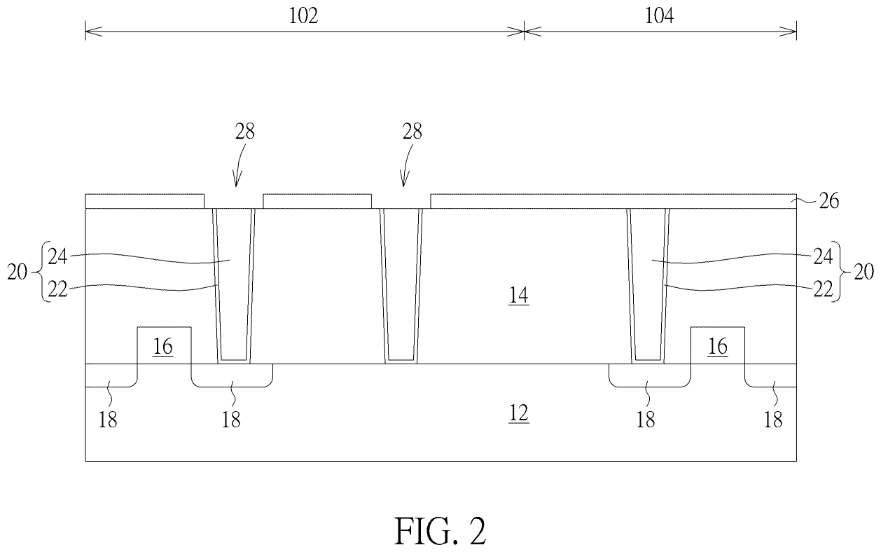

Next, as shown in FIG. 2, a photo-etching process is conducted by using a patterned mask (not shown) as mask to remove part of the stop layer 26 on the memory region 102 through etching for forming recesses 28 in the stop layer 26 and exposing the contact plugs 20. It should be noted that the recesses 28 are only formed on the memory region 102 in this stage hence the surface of the contact plugs 20 on the logic region 104 is still covered by the stop layer 26.

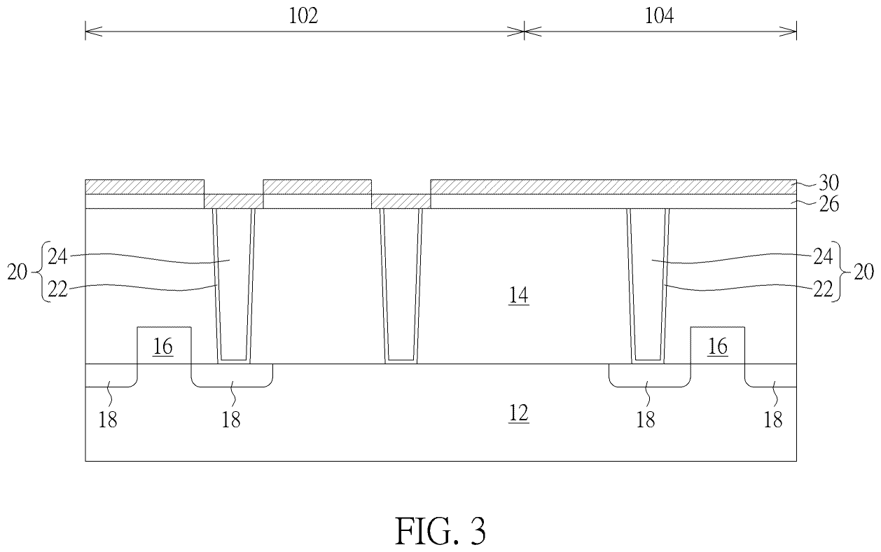

Next, as shown in FIG. 3, a bottom electrode 30 is formed on the stop layer 26 and into the recesses 28 to fill the recesses 28 completely. Preferably, the bottom electrode 30 is made of metal nitride such as tantalum nitride (TaN).

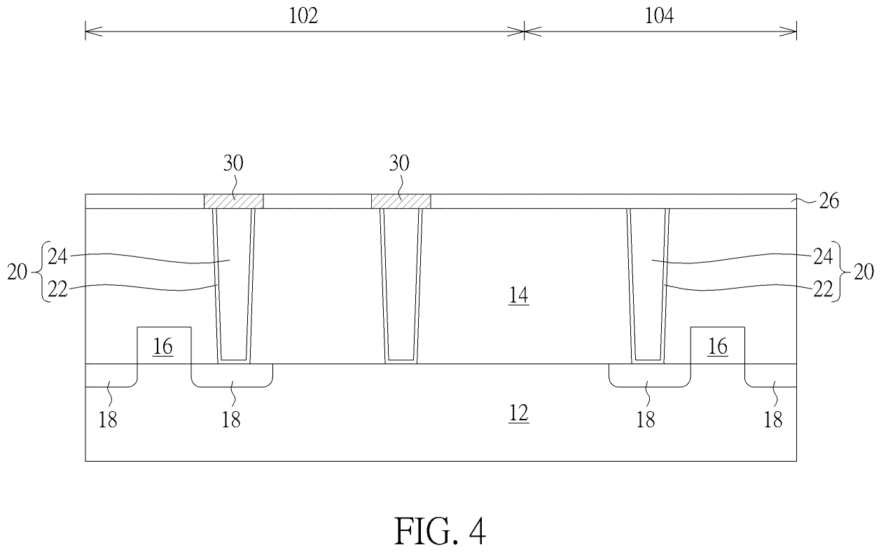

Next, as shown in FIG. 4, a planarizing process such as CMP is conducted to remove all of the bottom electrode 30 on top of the stop layer 26 so that the remaining bottom electrode 30 is embedded in the stop layer 26 while the top surface of the bottom electrode 30 is even with the top surface of the stop layer 26.

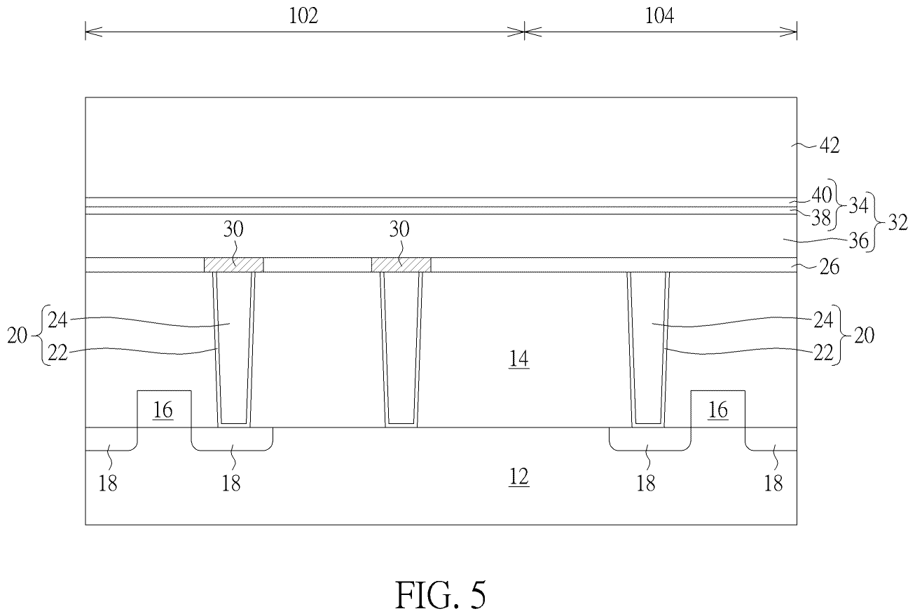

Next, as shown in FIG. 5, a resistance sensing device layer 32 and a top electrode 42 are formed on the surface of the bottom electrode 30 and stop layer 26. In this embodiment, the resistance sensing device layer 32 further includes a metal oxide layer 36 and a stop layer 34 made of a metal layer 38 and another metal layer 40. Preferably, the metal oxide layer 36 includes tantalum oxide (TaO), the metal layer 38 includes iridium (Ir), the metal layer 40 includes ruthenium (Ru), and the top electrode 42 includes metal nitride such as titanium nitride (TiN).

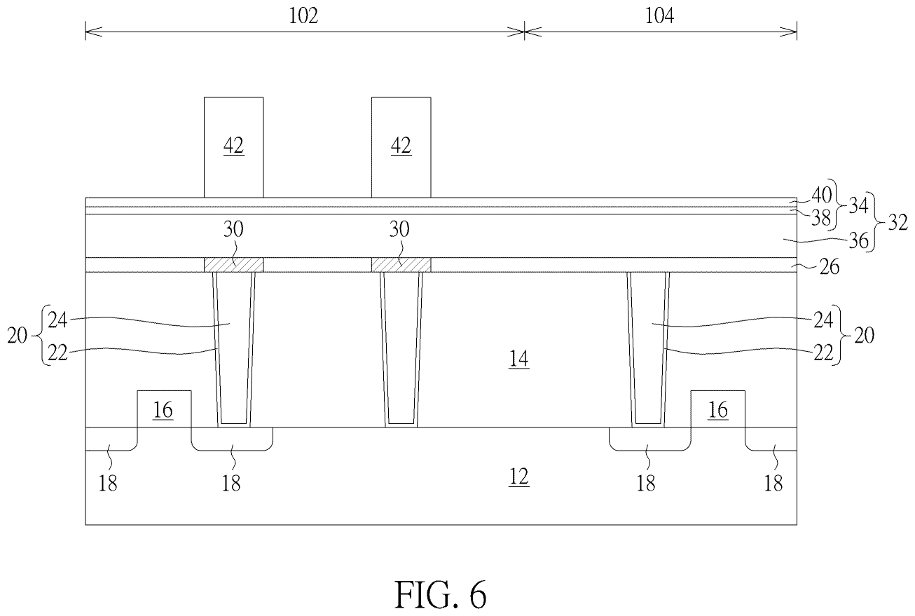

Next, as shown in FIG. 6, an etching process is conducted by using a patterned mask (not shown) as mask to remove part of the top electrode 42 and top on the surface of the stop layer 34. In this embodiment, the etching process conducted to pattern the top electrode 42 could include reactive ion etching (RIE) or ion beam etching (IBE) process, but not limited thereto.

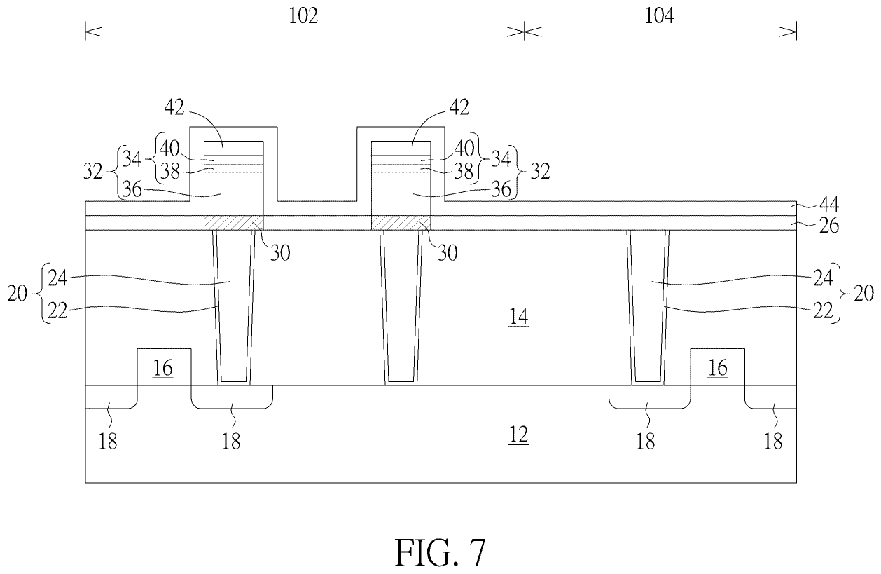

Next, as shown in FIG. 7, after the patterned mask is removed, one or more etching process could be conducted by using the patterned top electrode 42 as mask to remove part of the metal layer 40, part of the metal layer 38, and part of the resistance sensing device layer 32, and then a cap layer 44 is formed on the surface of the stop layer 26, sidewalls of the resistance sensing device layer 32 and top electrode 42, and top surface of the top electrode 42. Preferably, the cap layer 44 includes silicon nitride (SiN) and the etching process conducted to pattern the above resistance sensing device layer 32 includes a RIE process, but not limited thereto.

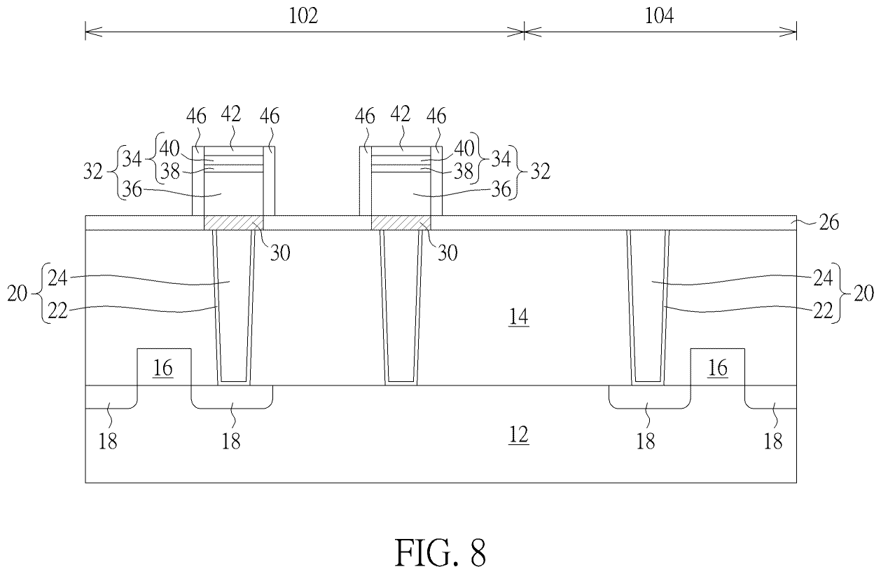

Next, as shown in FIG. 8, an etching process is conducted to remove part of the cap layer 44 for forming a spacer 46 adjacent to the top electrode 42 and resistance sensing device layer 32, in which the top surface of the spacer 46 is even with the top surface of the top electrode 42.

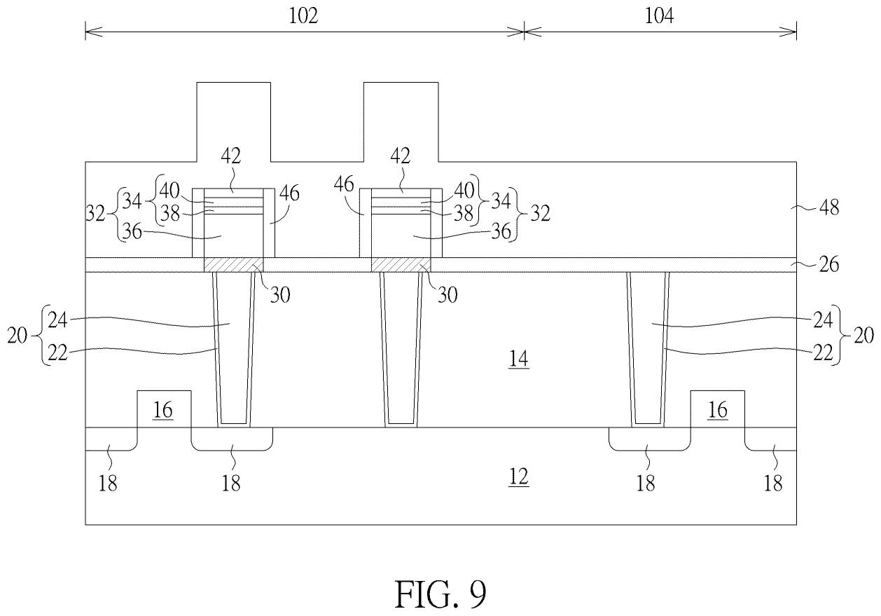

Next, as shown in FIG. 9, a flowable chemical vapor deposition (FCVD) process could be conducted to form an inter-metal dielectric (IMD) layer 48 on the stop layer 26 and the top electrode 42. In this embodiment, the IMD layer 48 is preferably made of silicon oxide or ultra low-k (ULK) dielectric layer including but not limited to for example porous material or silicon oxycarbide (SiOC) or carbon doped silicon oxide (SiOCH).

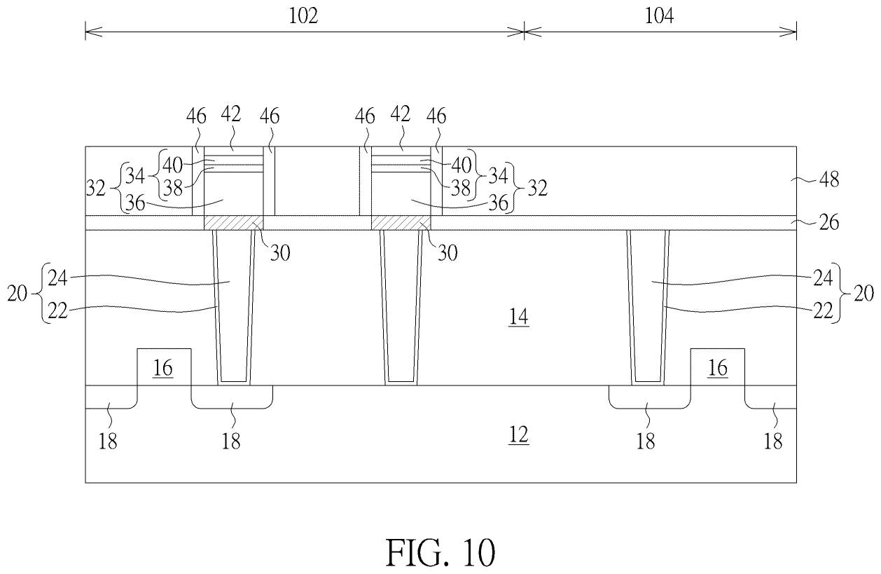

Next, as shown in FIG. 10, a planarizing process such as CMP is conducted to remove part of the IMD layer 48 on both the memory region 102 and logic region 104 so that the top surfaces of the IMD layer 48 and top electrode 42 on memory region 102 and logic region 104 are coplanar.

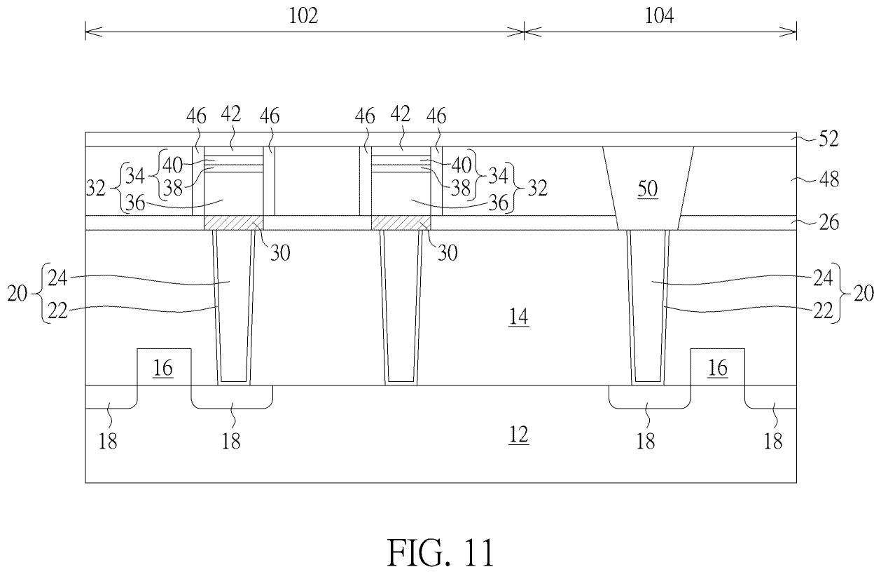

Next, as shown in FIG. 11, a patterned transfer process could be conducted by using a patterned mask (not shown) as mask to remove part of the IMD layer 48 and part of the stop layer 26 on the and logic region 104 for forming a contact hole (not shown) exposing the contact plug 20 underneath. Next, metal or conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact hole, and then a planarizing process such as CMP process is conducted to remove part of the metals for forming a contact plug or metal interconnection 50 in the contact hole electrically connecting the contact plug 20 underneath. Next, another stop layer 52 is formed on the IMD layer 48 on both memory region 102 and logic region 104. Similar to the above stop layer 26, the stop layer 52 is made of nitrogen doped carbide (NDC), silicon nitride, silicon carbon nitride (SiCN), silicon oxynitride (SiON), or combination thereof. This completes the fabrication of a semiconductor device according to an embodiment of the present invention.

Referring again to FIG. 11, FIG. 11 further illustrates a structural view of a semiconductor device according to an embodiment of the present invention. As shown in FIG. 11, the semiconductor device includes an ILD layer 14 disposed on the substrate 12, a contact plug 20 disposed in the ILD layer 14, a bottom electrode 30 disposed on the contact plug 20, a stop layer 26 around the bottom electrode 30, a resistance sensing device layer 32 disposed on the bottom electrode 30, a top electrode 42 disposed on the resistance sensing device layer 32, a spacer 46 disposed on sidewalls of the resistance sensing device layer 32 and the top electrode 42, and an IMD layer 48 around the spacer 46.

Specifically, the resistance sensing device layer 32 further includes a metal oxide layer 36 and a stop layer 34 made of a metal layer 38 and another metal layer 40, in which the metal oxide layer 36 includes tantalum oxide (TaO), the metal layer 38 includes iridium (Ir), the metal layer 40 includes ruthenium (Ru), and the top electrode 42 includes metal nitride such as titanium nitride (TiN). Moreover, the left and right sidewalls of the bottom electrode 30 are aligned with left and right sidewalls of the resistance sensing device layer 32 and top electrode 42 atop, the bottom surface and top surface of the bottom electrode 30 are even with bottom surface and top surface of the surrounding stop layer 26, and the bottom electrode 30 is directly connected to the source/drain region 18 of the active device such as MOS transistor on the substrate 12 through the contact plug 20. In other words, only a single level of conductive line such as the contact plug 20 instead of two, three, or more layers metal conductive structures is disposed between the source/drain region 18 and the bottom electrode 30.

Overall, the present invention discloses a method for fabricating resistive random access memory (RRAM) device, which first forms at least a contact plug 20 in an ILD layer 14 to electrically connect or directly contacting source/drain regions of active device such as MOS transistor on the substrate, forms a stop layer 26 on the ILD layer, removes part of the stop layer to form recess exposing the contact plug, forms bottom electrode on the stop layer and into the recess to fill the recess completely, removes the bottom electrode on the surface of the stop layer through planarizing process so that the remaining bottom electrode only fills the recesses completely, and then forms a resistance sensing device layer 32 and top electrode 42 on the bottom electrode for forming a RRAM device. By using the above damascene approach to form bottom electrode directly on top of the contact plug while the top surface of the bottom electrode is even with the top surface of stop layer on two adjacent sides, it would be desirable to boost up accuracy when the bottom electrode and contact plug underneath are aligned, which further reduces error generated between these two elements thereby improving overall performance of the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a resistive random access memory (RRAM), comprising:
forming an interlayer dielectric (ILD) layer on a substrate;
forming a contact plug in the ILD layer; and
forming a bottom electrode on the contact plug and a first stop layer around the bottom electrode.

2. The method of claim 1, further comprising:
forming the first stop layer on the ILD layer;
forming a recess in the first stop layer;
forming the bottom electrode in the recess;
forming a metal oxide layer on the bottom electrode;
forming a top electrode on the metal oxide layer;
patterning the top electrode and the metal oxide layer;
forming a spacer adjacent to the top electrode and the metal oxide layer.

3. The method of claim 2, further comprising forming a second stop layer on the metal oxide layer before forming the top electrode.

4. The method of claim 3, wherein the second stop layer comprises metal.

5. The method of claim 3, wherein the second stop layer comprise:
a first metal layer on the metal oxide layer; and
a second metal layer on the first metal layer.

6. The method of claim 2, further comprising:
forming a cap layer on the top electrode;
removing part of the cap layer to form the spacer.

7. The method of claim 1, wherein top surfaces of the bottom electrode and the first stop layer are coplanar.

8. A resistive random access memory (RRAM), comprising:
an interlayer dielectric (ILD) layer on a substrate;
a contact plug in the ILD layer;
a bottom electrode on the contact plug; and
a first stop layer around the bottom electrode.

9. The resistive random access memory of claim 8, further comprising:
a metal oxide layer on the bottom electrode
a top electrode on the metal oxide layer; and
a spacer adjacent to the metal oxide layer and the top electrode.

10. The resistive random access memory of claim 8, further comprising a second stop layer between the metal oxide layer and the top electrode.

11. The resistive random access memory of claim 10, wherein the second stop layer comprises metal.

12. The resistive random access memory of claim 10, wherein the second stop layer comprise:
a first metal layer on the metal oxide layer; and
a second metal layer on the first metal layer.

13. The resistive random access memory of claim 9, wherein top surfaces of the bottom electrode and the first stop layer are coplanar.
